(19) United States
(12) Patent Application Publication
(10) Pub. No.: US 2009/0236540 A1
(43) Pub. Date: Sep. 24, 2009

(54) STAGE AND ELECTRON MICROSCOPE APPARATUS

(75) Inventors: Eiichi SEYA, Hitachinaka (JP); Takashi Nagamatsu, Hitachinaka (JP)

Correspondence Address: MILES & STOCKBRIDGE PC, 1751 PINNACLE DRIVE, SUITE 500, MCLEAN, VA, 22102-3833, US

(73) Assignee: HITACHI HIGH-TECHNOLOGIES CORPORATION

(21) Appl. No.: 12/393,580

(22) Filed: Feb. 26, 2009

(30) Foreign Application Priority Data
Mar. 18, 2008 (JP) 2008-068660

(51) Int. Cl. H01J 37/20

(52) U.S. Cl. 250/442.11

(57) ABSTRACT

A sample stage for electron microscope according to an embodiment of the invention includes at least two actuators capable of expanding and contracting or capable of swinging for moving a target sample in a predetermined direction. With a coordination of the two actuators, various controls are available by combining the operations of the two actuators. Accordingly, a stage mechanism capable of reducing a stop drift as well as moving a stage can be provided.

### BACKGROUND OF THE INVENTION

1. Field of the Invention

The present invention relates to an electron microscope and a stage mechanism for an electron microscope, and more particularly, to an electron microscope that are suitable for measuring dimensions of fine patterns of a semiconductor device or observing the fine patterns and a stage mechanism for the electron microscope.

2. Background Art

A scanning electron microscope (SEM) is used in various fields of research and development, and has been applied in a manufacturing field in recent years. In particular, the measurement of dimensions of fine structure or observation of the fine structure, which is performed by a scanning electron microscope, becomes necessary in a process for manufacturing a semiconductor.

The design rule of a semiconductor integrated circuit becomes finer every year, then the width of a pattern reaches 100 nm or less. Accordingly, a length measuring SEM or a review SEM is used to measure dimensions of fine patterns, to observe the shape of the fine patterns, or to observe the defects of foreign materials. For example, the length measuring SEM among them, which is an apparatus used for measuring the width of a circuit pattern, includes an electron optical system that converges an electron beam and scans, a sample chamber and a stage for positioning a wafer, which is a sample, in a vacuum.

Conventionally, a structure using a sliding screw as driving means has been generally employed in the sample stage of the electron microscope for inspecting and measuring a semiconductor. However, in recent years, in order to improve positioning speed and accuracy, and to avoid chemical pollution of a wafer caused by a lubricant oil, there has been proposed a stage using an ultrasonic motor, which is a linear actuator using a piezoceramic actuator (piezo actuator), as a drive source (see Japanese Patent Application Laid-Open (JP-A) No. 3-129653 (corresponding to U.S. Pat. No. 5,149,967) and Japanese Patent No. 3834486).

There are some types as a specific structure of the ultrasonic motor. However, the types of the ultrasonic motor may be broadly classified into (1) a type that generates a surface elastic wave on a surface contacting an object to be slid, and (2) a type that displaces or vibrates a driving part contacting an object to be slid by deformation of an actuator. In general, the type (2) using the deformation of the actuator is suitable for the electron microscope for a semiconductor requiring a large slide stage since being capable of sliding a heavy object at high slide speed.

Further, the type (2) may be classified into a type that uses the resonance of a motor structure and a non-resonant type that does not resonate. An example disclosed in Japanese Patent Application Laid-Open (JP-A) No. 7-184382 (corresponding to U.S. Pat. No. 6,064,140) is a type that uses resonance in an ultrasonic motor using the deformation of an actuator, and vibrates a ceramic spacer (driving part) by the combination of the resonance in an expansion and contraction mode of a piezoelectric plate in a longitudinal direction and the resonance in a bend mode, thereby driving an object. In this case, there has been disclosed that a slide direction can be changed by switching a phase relationship between the two kinds of resonance into a positive or negative relationship.

Further, an example of a non-resonant ultrasonic motor structure has been disclosed in Japanese Patent No. 3834486. In this example, two actuators, which can expand and contract and be displaced at an end in a transverse direction, are employed in parallel. Drive voltages are applied so that a phase difference between the respective expansions and contractions and transverse displacements becomes 90°. Accordingly, the end (driving part) is moved in elliptical form, so that the object is driven.

In the electron microscope for inspecting and measuring a semiconductor, an observation portion of a sample is moved to a field of observation view at high speed by a stage, and an electron beam is irradiated onto the observation portion in a vacuum chamber for observation and measurement. Meanwhile, if drift occurs on a sample stage, that is, if the stop position of the sample is minutely deviated with time after the sample is completely positioned while the sample is observed with high magnification, there is a problem in that measurement accuracy deteriorates during the measurement of the dimensions of fine patterns.

In recent years, in the electron microscope for inspecting and measuring a semiconductor, the resolution of a beam reaches about 1.5 nm, and the measurement reproducibility of 0.2 nm has been required for measuring the width of the fine pattern. For this reason, drift needs to be suppressed to 0.5 nm/sec or less during a period of 1 to 2 seconds after the stage is stopped, until the stage starts to move toward the next portion to be measured.

Meanwhile, since an electron beam can be electrically deviated, the required positioning accuracy of the stage is about 1 μm. Even if the positioning error of such degree is generated, the object pattern on the wafer can be positioned at the center of an image by the deviation of the beam prior to the observation and measurement. However, in order to compensate the drift by the deviation of a beam, compensation should be performed in real-time during the observation and measurement. Accordingly, the compensation needs to be performed with high speed and accuracy. As a result, there are problems in that the circuit is complicated and that the electrical resistance against external noise deteriorates.

As described above, a permissible value of drift in positioning accuracy is stricter by 1000 times or more in the electron microscope for inspecting and measuring a semiconductor while such strict performance is not needed in other fields.

In the ultrasonic motor and the stage using the ultrasonic motor, which are disclosed in JP-A Nos. 3-129653 (corresponding to U.S. Pat. No. 5,149,967) and 7-184382 (corresponding to U.S. Pat. No. 6,064,140) and Japanese Patent No. 3834486, positioning can be performed with high speed and accuracy, but the drift has been not considered. Accordingly, if the ultrasonic motor and the stage using the ultrasonic motor are used in the electron microscope for inspecting and measuring a semiconductor, there is a problem in that it is difficult to reduce drift.

An ultrasonic motor using a piezo electric actuator has residual deformation of the piezo electric actuator as a peculiar problem. The residual deformation is a phenomenon where the piezo electric actuator continues to be minutely deformed even though the drive voltage is kept constant after the piezo electric actuator is deformed in quick response to the change of a drive voltage. The residual deformation causes drift. Meanwhile, the magnitude of the residual deformation is generally about 1 μm or less and does not cause a problem in an application that does not strictly require low drift of the stage. However, drift causes a serious problem in the electron microscope for inspecting and measuring a semiconductor where a permissible value of drift is strict as described above.

### SUMMARY OF THE INVENTION

The object of the present invention is to provide a stage mechanism that has small drift when stopped and an electron microscope apparatus using the stage mechanism.

According to an embodiment of the invention, there is provided a sample stage. The sample stage includes two or more driving actuators, which can expand and contract or slide, and moves a stage by the cooperation of the two driving actuators. With a coordination of the two driving actuators, various controls are available by combining the operations of the two driving actuators. Accordingly, a stage mechanism capable of reducing a stop drift as well as moving a stage can be provided.

According to the embodiment of the invention, it may be possible to achieve a sample stage that has small drift when stopped, and an electron microscope using the sample stage.

### DESCRIPTION OF DRAWINGS

FIG. 1 is a schematic view showing the configuration of an electron microscope apparatus according to an embodiment of the invention;

FIG. 2 is a schematic view showing the configuration of a stage of the electron microscope apparatus according to the embodiment of the invention;

FIG. 3 is a view showing a structural example of an ultrasonic motor;

FIGS. 4A and 4B are views showing the operation of the ultrasonic motor;

FIG. 5 is a view showing the trajectory of a drive tip of the ultrasonic motor;

FIG. 6 is a view showing an example of the drive circuit;

FIG. 7 is a view showing the residual deformation characteristics of a piezo electric actuator;

FIG. 8 is a view showing applied voltage-deformation characteristics of the piezo electric actuator;

FIG. 9 is view a showing applied voltage-deformation characteristics of the piezo electric actuator;

FIG. 10 is view showing another example of the drive circuit;

FIG. 11 is a view showing still another example of the drive circuit;

FIGS. 12A and 12B are views showing another structural example of the ultrasonic motor;

FIG. 13 is a flowchart showing an example of a procedure for reducing drift;

FIG. 14 is a flowchart showing another example of the procedure for reducing drift; and

FIG. 15 is a view illustrating a relationship between the dispositions of two piezo electric actuators in three dimensions.

### DESCRIPTION OF PREFERRED EMBODIMENT

In a sample stage according to an embodiment of the invention that is driven by an ultrasonic motor including piezo electric actuators disposed at angles symmetric about a surface to be driven while stopping in positioning, after positioning conditions are satisfied, a phase difference in the variation of a drive voltages applied to the piezo electric actuators is kept for a predetermined time O.

Alternatively, in the same sample stage while stopping in positioning, after positioning conditions are satisfied, a drive voltage is fixed at a time when a phase of the variation of a drive voltage applied to each of the piezo electric actuators becomes a predetermined phase. Further, this cutoff phase is determined according to the positioning stop coordinates and moving direction of the stage immediately before the stop in positioning.

Further, a sample stage includes a piezo electric actuator that presses a drive tip against the surface to be driven, and a piezo electric actuator that moves the drive tip in a driving direction. After positioning conditions are satisfied while stopping in positioning, an applied voltage is fixed at a time when a phase of a voltage applied to the latter piezo electric actuator becomes a predetermined phase. Further, the cutoff phase is a phase corresponding to a point where a deformation response to the applied voltage by the piezo electric actuator intersects with a deformation convergence line of the piezo electric actuator.

In addition, an electron microscope includes these sample stages.

Further, in order to control the sample stage that is driven by the ultrasonic motor, the electron microscope includes a phase difference oscillating circuit that controls a phase difference of a variations of a voltages respectively applied to a pair of the piezo electric actuators of the ultrasonic motor, and a delay circuit and a hold circuit for maintaining the phase difference of the variations of the applied voltages for a predetermined time after positioning conditions are satisfied and then fixing the phase difference. Further, the electron microscope further includes a memory circuit that stores a phase difference value to be added to an input of the phase difference oscillating circuit in association with a moving direction of the stage and a positioning coordinate.

Alternatively, electron microscope includes a similar phase difference oscillating circuit, and a synchronization circuit and a hold circuit for fixing the applied voltages at a time when the applied voltages reach predetermined phases after positioning conditions are satisfied. Further, the electron microscope further includes a memory circuit that stores a phase difference value to be added to an input of the phase difference oscillating circuit and a cutoff phase to be input to the fixing circuit in association with positioning coordinates and a moving direction of the stage.

Further, an electron microscope includes a sample stage that is driven by a linear drive source, such as an ultrasonic motor or a linear motor. The electron microscope has a mechanism, in which steps for (1) positioning the sample stage, and (2) evaluating a stage drag while stopping in positioning are performed for the positioning from both directions of a moving axis at points of a plurality of coordinates that are disposed within a movement stroke of the sample stage, so as to measure the distribution of a stop drag of the stage within the movement stroke and then based on the measurement result, drift during the positioning of the stage is reduced.

Alternatively, an similar electron microscope has a mechanism, in which steps for (1) positioning the sample stage, (2) evaluating drift after stop, and (3) compensating a control parameter of the stage are repeated at points of a plurality of coordinates that are disposed within a movement stroke of the sample stage, so as to reduce drift of the stage within the movement stroke.

In addition, the mechanism for reducing the stop drift may be automatically performed by issuing an operation command.

An embodiment of the invention will be described below with reference to drawings. Meanwhile, a length measuring SEM is exemplified as an aspect of an SEM in the following description, but the invention is not limited thereto. For example, the invention may be applied to a review SEM that has been described above, particularly, a general charged particle beam apparatus that performs fine measurement, inspection, processing, observation, and the like.

### Example 1

### Application and Apparatus

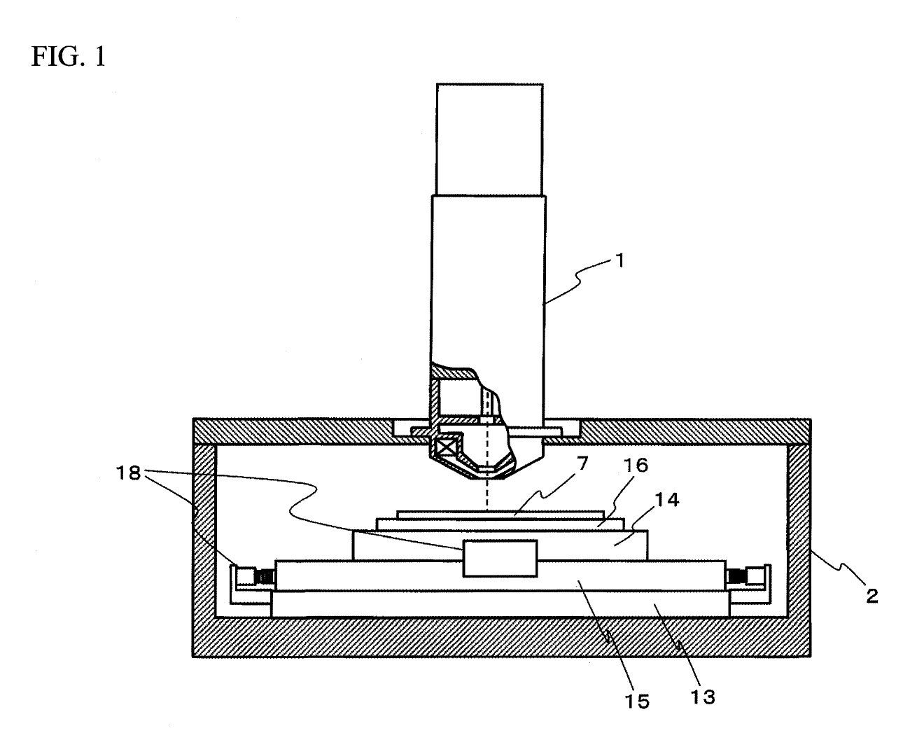

FIG. 1 is a schematic view showing the configuration of a length measuring SEM according to an embodiment of the invention. The length measuring SEM according to the embodiment of the invention includes a charged-particle optical system 1, a sample chamber 2 that keeps a wafer (sample) 7 in a vacuum, and a sample stage that moves the wafer 7. The length measuring SEM scans the wafer 7 with a charged particle beam that is emitted from the charged-particle source and thinly focused on the wafer, obtains a scanned image of the wafer 7 by detecting secondary electrons that are emitted from the wafer 7, and measures the dimensions of fine patterns formed on the wafer from signals of the scanned image.

The sample chamber 2 is kept in a vacuum state, which corresponds to a vacuum pressure of about 10⁻⁴ Pa, by a vacuum pump (not shown) or the like. The sample stage disposed in the sample chamber 2 is a mechanism that moves and positions an arbitrary portion of the wafer to a length measurement position, onto which electron beams are irradiated, at high speed.

### (Configuration of Stage)

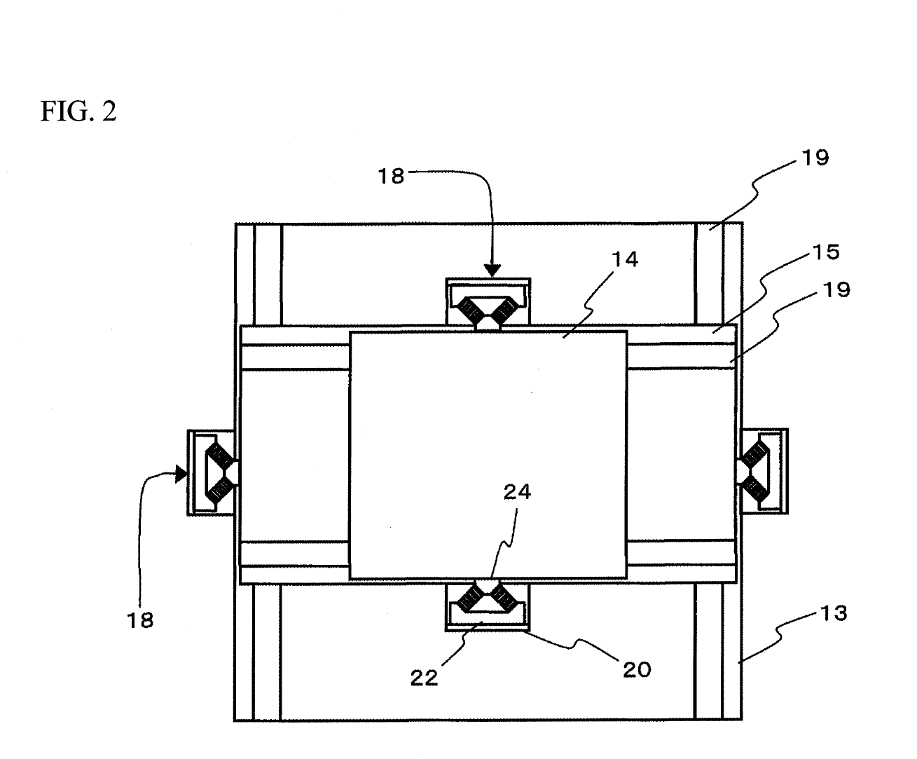

FIG. 2 shows the basic configuration of the sample stage. The sample stage mainly includes a base 13, a Y table 15 that is moved on the base 13, and an X table 14 that is moved on the Y table 15. A chuck mechanism 16, which fixes the wafer 7, is provided on the X table 14. Each of the tables is supported so as to be moved on rails 19, and is moved and positioned by ultrasonic motors 18. The ultrasonic motors 18 are positioned to sandwich each of the tables so as to stably accelerate, decelerate, position, and fix the table.

### (Operation of Motor)

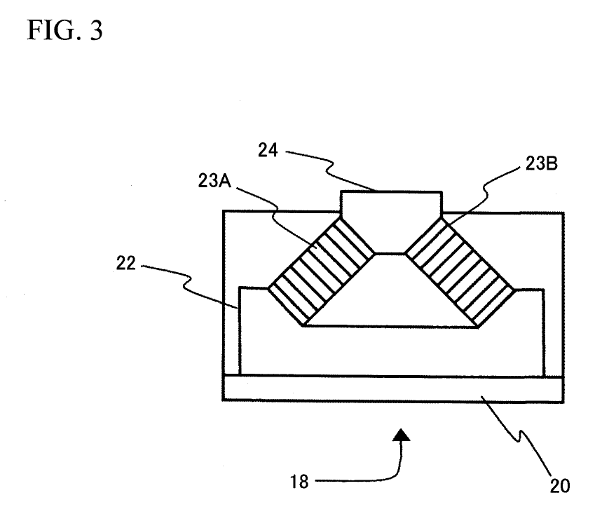

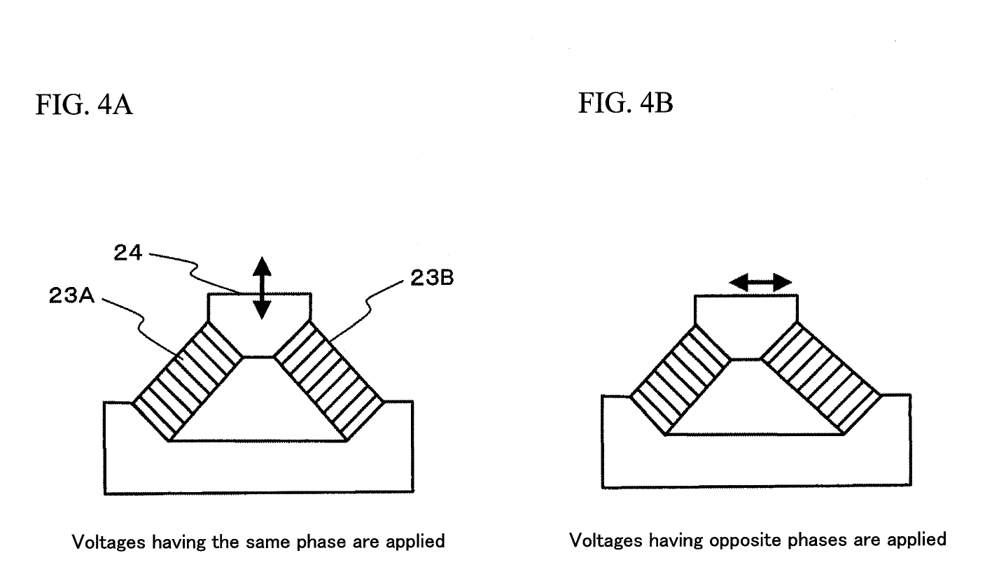

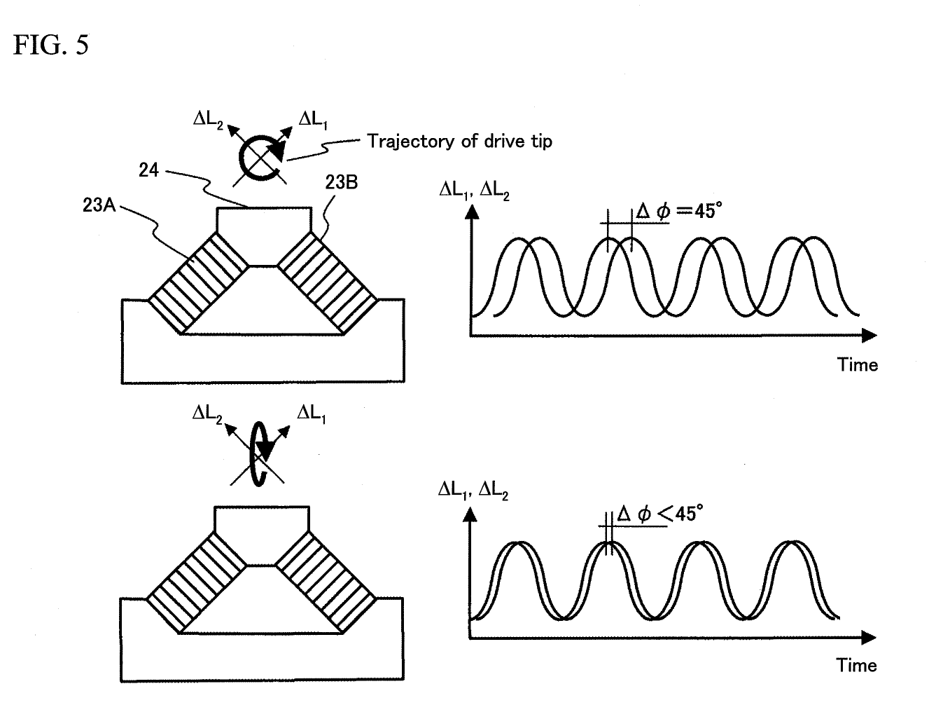

The structure of the ultrasonic motor 18 is shown in FIG. 3. The ultrasonic motor 18 includes a pair of piezo electric actuators 23A and 23B that is fixed to form an angle therebetween, and the ends of the piezo electric actuators are fixed to a common drive tip 24. The end face of the drive tip 24 comes in contact with a drive face formed on the side surface of the table that is an object to be driven. Accordingly, the table is driven by the vibration of the drive tip 24. If voltages varying with the same phase are applied to the piezo electric actuators 23A and 23B as shown in FIG. 4, the drive tip 24 causes displacement in a direction perpendicular to the drive face by the expansion and contraction of the actuators. Further, if the voltages having opposite phases are applied to the piezo electric actuators, the drive tip causes displacement in a slide direction of the stage. Accordingly, the ultrasonic motor may be used as an ultrasonic linear actuator by using the displacement. If drive voltages, which include sinusoidal voltages having different phases, are applied to the piezo electric actuators, the trajectory of the displacement of the drive tip has a shape similar to an elliptical shape that corresponding to the Lissajous waveform of the voltages as shown in FIG. 5. When the phase difference is 90°, this trajectory has a circular shape. The rotational direction of the drive tip is reversed according to the correspondence of the phase difference. Since the transverse moving speed of the most protruding portion is large in this state, it may be possible to drive the stage at high speed. If the phase difference between the applied voltages is decreased, the trajectory has the shape of an ellipse elongated in a vertical direction. Since the transverse moving speed of the most protruding portion is decreased, the moving speed of the stage is decreased. When the phase difference is 0°, the drive tip is vibrated only in a direction perpendicular to an object surface to be fed, so that a driving force is not generated.

Meanwhile, it is preferable that a driving frequency be 20 kHz or more. Like in the case of a known resonant ultrasonic motor, when the drive tip recedes, the contact between the drive tip and the object surface to be fed is not maintained during the vibration in this band. As a result, the drive tip drives the object surface by the transverse displacement speed in an area close to a protruding end of the Lissajous waveform.

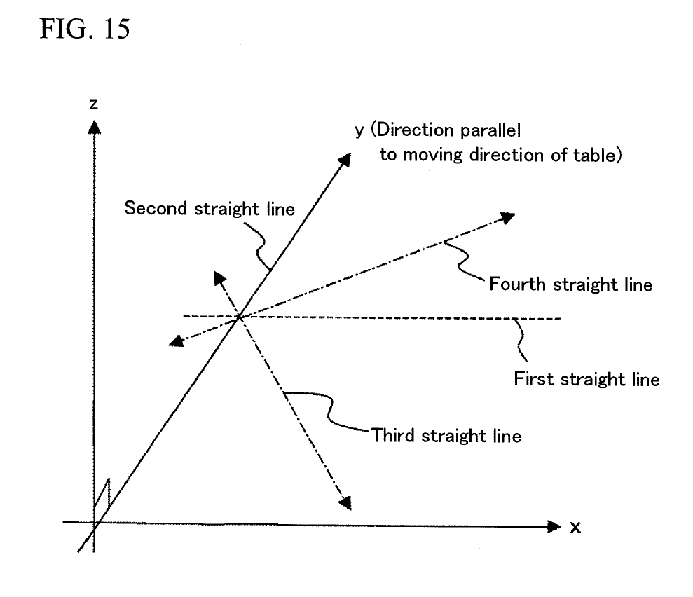

FIG. 15 is a view illustrating a relationship between the dispositions of the two piezo electric actuators in three dimensions. The relationship between the dispositions in FIG. 15 is only illustrative, and may be modified in various ways without departing from the scope and spirit of the invention. When being seen in three dimensions as shown in FIG. 15, the two piezo electric actuators 23A and 23B are disposed so that the expansion-contraction directions of the piezo electric actuators correspond to third and fourth straight lines, respectively. The third and fourth straight lines are positioned in a plane (an X-Y plane in FIG. 15) including a first straight line that is a line perpendicular to the drive face (a Y-Z plane in FIG. 15) and a second straight line that is a y axis in FIG. 15. Further, the third and fourth straight lines are disposed symmetrically about the first straight line.

According to the above-mentioned disposition, it may be possible to press the drive tip 24 against the drive face or to separate the drive tip from the drive face by the cooperation of the piezo electric actuators 23A and 23B.

### (Positioning and Circuit)

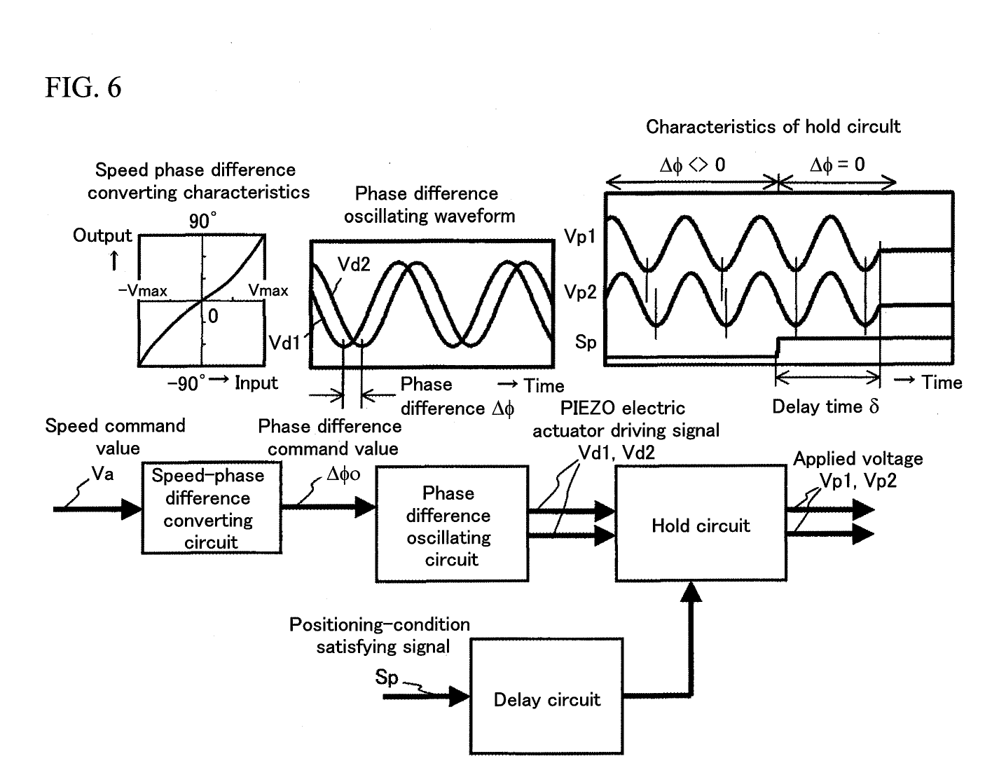

FIG. 6 shows an example of a drive control circuit of the ultrasonic motor. In this example, so-called trapezoidal speed control is used for the positioning movement. Accordingly, when the table starts and when the positioning of the table is stopped, the moving speed of the table is linearly changed with time. In order to achieve speed control, as shown in FIG. 6, a speed command value is converted into a phase difference command value Δφo by a speed-phase difference converting circuit with the change of the phase difference so that the phase differences are suppressed, and piezo electric actuator driving signals Vd1 and Vd2 having the same phase difference as Δφ0 are generated by a phase difference oscillating circuit. A hold circuit is provided to fix applied voltages Vp1 and Vp2 when the table reaches a target position. Accordingly, if the applied voltages are fixed, the ultrasonic motor 18 stops the vibration and the table is fixed by the ultrasonic motor 18.

### (Generation of Drift)

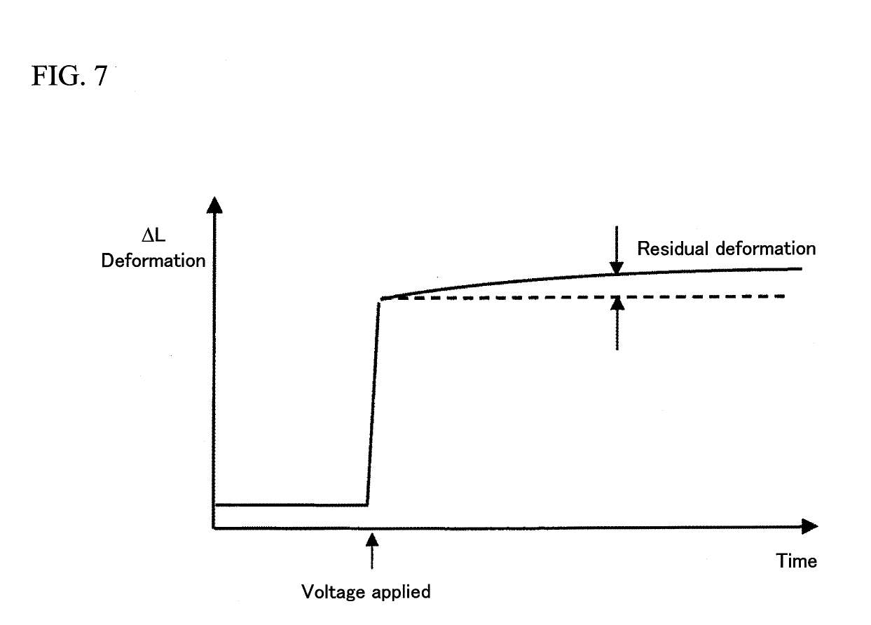

The peculiar drift generated by the piezo electric actuator will be described below. FIG. 7 is a view showing the general characteristics of the residual deformation of the piezo electric actuator used in the ultrasonic motor 18, and a horizontal axis represents elapsed time and a vertical axis represents the deformation ΔL of the piezo electric actuator. If a voltage is applied or removed to or from the piezo electric actuator, the piezo electric actuator expands or contracts. Since the response speed of the piezo electric actuator is very high, the piezo electric actuator is instantaneously deformed by the application of the voltage. However, there has been widely known that residual deformation is gradually generated according to the elapsed time thereafter although not much.

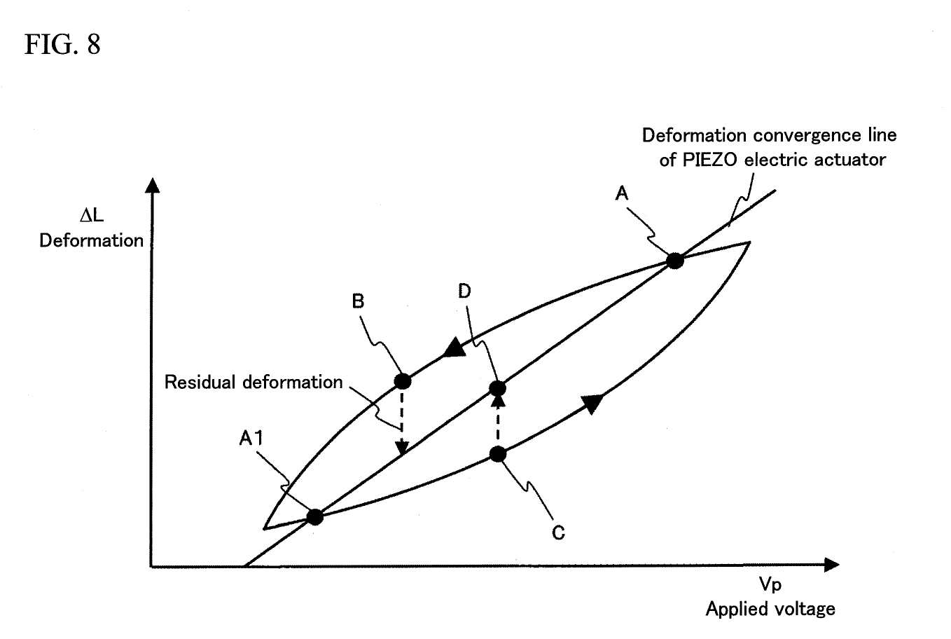

Since the polycrystal orientation of the actuator is rotated due to an electric field that is generated inside the piezo electric actuator by the application of a drive voltage, the deformation of the piezo electric actuator is generated. However, since internal friction is applied to the rotation, hysteresis occurs in an applied voltage-deformation graph. This relationship is shown in FIG. 8. The graph plots a loop where the deformation does not correspond to the same value when the applied voltage is increased and decreased.

If an applied voltage is fixed at a point C on the loop in FIG. 8, the rotation of the crystal orientation, which is restricted without reaching a stable point due to internal friction, is gradually released due the thermal motion of molecules with time. As a result, the piezo electric actuator is gradually deformed to extend and finally converges to a point D that is a stable point. Meanwhile, this stable point is determined depending on the electric field that is generated by an applied voltage, and forms a linear graph. Accordingly, the linear graph is referred to as a deformation convergence line herein. It can be seen from the graph as follows: for example, if a voltage is fixed at a point B while the applied voltage is decreased, residual deformation is generated on the lower side of FIG. 8 in contrast to the case of the point C.

The piezo electric actuators of the ultrasonic motor 18 are provided with an angle therebetween not to be parallel to a pressing direction where the ultrasonic motor is pressed against the surface to be driven. Accordingly, if the piezo electric actuator has the residual deformation after the positioning, displacement is generated in a direction where the drive tip 24 fixing the table moves the table, which causes drift.

### (Same Phase Delay Cutoff)

However, the piezo electric actuators 23A and 23B are symmetrically disposed. Accordingly, when the same residual deformation is generated, the drive tip 24 generates the displacement only in the pressing direction, so that drift is not generated. If the table reaches near a positioning point in a normal positioning operation, the table is stopped at the positioning point by the position servo. However, since the motor generates a thrust due to a residual friction force in this case, the voltages applied to the piezo electric actuators are not same as in normal case. In this example, after the table reaches near the positioning point, the phase difference between the applied voltages Vp1 and Vp2 is kept at 0° for a short time δ. Then, after the deformation hysteresis of the piezo electric actuators is kept evenly, the drive is cut off and the applied voltages are fixed. Since the voltages applied to the piezo electric actuators 23A and 23B are equal to each other for the time δ, residual deformation becomes equal after drive cutoff. If about several cycles of the driving frequency or 1/100 or less of a normal positioning time is delayed, δ is sufficiently effective. Meanwhile, if driving is performed immediately before the positioning while the phase difference is kept at 0° without employing the position servo unlike the invention, a deviation of about 1 μm or less occurs in the position of the table due to the residual friction force and the like. However, as described above, as for the stage mechanism of the electron microscope that is used to inspect and measure a semiconductor, a permissible value of drift in positioning accuracy is stricter by 1000 times or more. Accordingly, the deterioration of this positioning accuracy does not affect the performance of the apparatus, and it may be possible to achieve the inspection and measurement accuracy caused by the reduction of the drift.

Meanwhile, it may be possible to prevent the piezo electric actuator from being deformed in the slide direction by the above-mentioned method, but residual deformation is generated in the pressing direction perpendicular to the slide direction. However, the support stiffness of the table is high in the direction perpendicular to the slide direction. In this example, the ultrasonic motors 18 are provided on both sides of the table so that the table is provided between the ultrasonic motors. Accordingly, the residual deformation is cut off in the pressing direction, and the movement of the table is not caused.

### Example 2

### Set Phase Cutoff

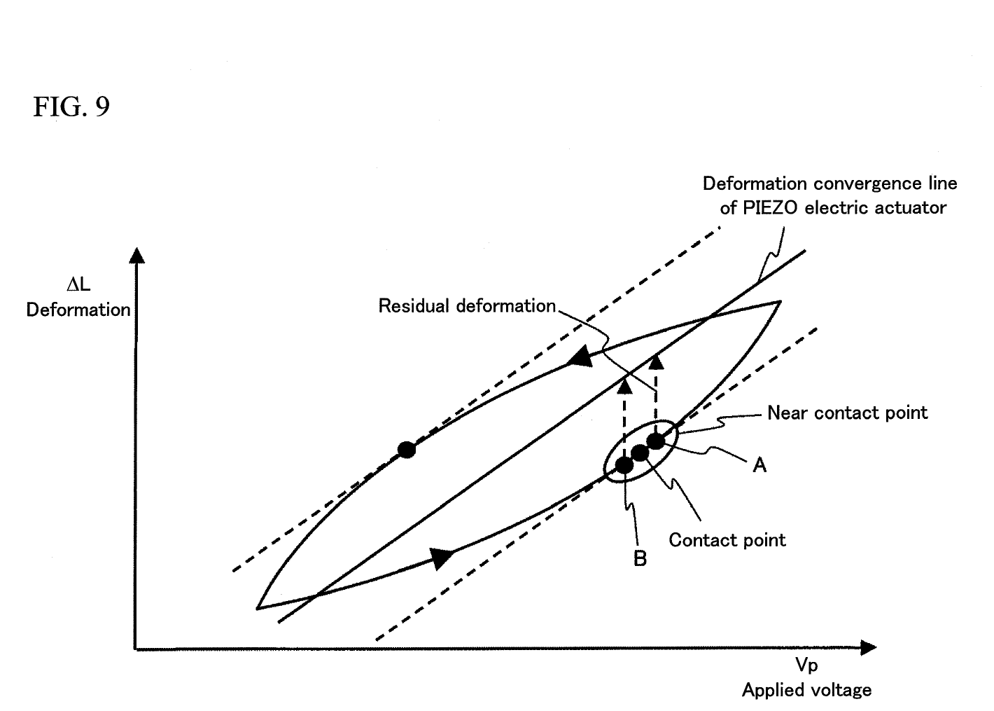

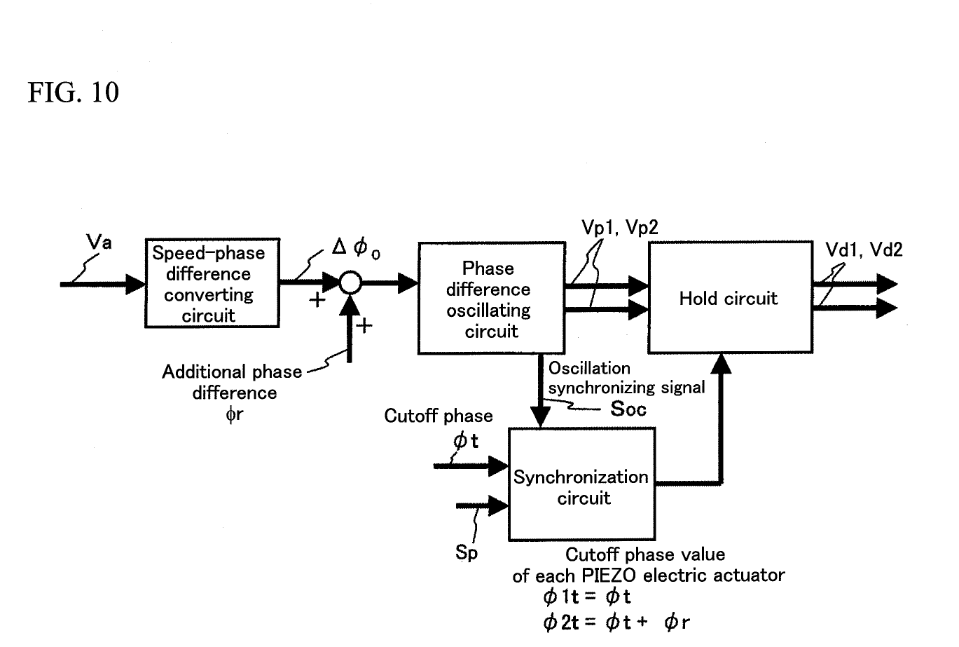

Another method of reducing the drift of the table in the same apparatus as Example 1 will be described with reference to FIGS. 9 and 10. Positioning accuracy has deteriorated due to the residual friction force in Example 1. However, since the positioning accuracy significantly deteriorates if the residual friction force is large, this is not necessarily preferable. Accordingly, a method of reducing drift by controlling the phase of drive cutoff without the deterioration of the positioning accuracy is used in this example.

FIG. 9 shows a method of controlling the residual deformation by using a cutoff phase in the same graph (a graph showing a relationship between deformation and the voltage applied to the piezo electric actuator) as FIG. 8. Oblique dotted lines in FIG. 9 are tangent lines that are tangent to the deformation characteristic graph and parallel to the deformation convergence line. In order to prevent the positioning accuracy from deteriorating during the positioning, the ultrasonic motor needs to generate a thrust of which the magnitude is equal to the magnitude of the residual friction force. However, there should be a phase difference between the applied voltages Vp1 and Vp2 that are applied to the piezo electric actuators. In this case, points representing the stare of each of the piezo electric actuators on the characteristics graph have positional deviations. In a normal control method, the control is cut off as soon as positioning conditions are satisfied. Accordingly, the piezo electric actuators have different residual deformation, so that drift is generated.

In this example, this problem is solved by limiting the timing of the control cutoff. A point A and a point B are shown near a contact point in FIG. 9. If the points disposed on both sides of the contact point are drive cutoff points, it can be seen that it may be possible to make the residual deformation be the same even though there is a phase difference. Further, it can be easily seen through simple consideration that the only two contact points of FIG. 9 satisfy this condition if the phase difference between the points A and B is small.

In this example, phase values φt1 and φt2 satisfying the above-mentioned condition are previously calculated, and the drift is reduced by performing the drive cutoff of the ultrasonic motor 18 under this condition. FIG. 10 shows an example of a drive circuit that achieves this. An additional phase value φr, which is used to generate the thrust corresponding to the residual friction force, is added to a phase difference command value Δφo that is an output of the same speed-phase difference converting circuit as that of Example 1. Further, after a positioning-condition satisfying signal Sp is input to a synchronization circuit, the synchronization circuit generates a signal that is delayed from an oscillation synchronizing signal Soc synchronized with Vp1 by a delay time corresponding to a cutoff phase φt, and the applied voltages Vd1 and Vd2 are fixed by the hold circuit. As a result, when “phase φt1=φt” is satisfied, the control for performing drive cutoff is always achieved for Vd1. Further, when “phase φt2=φt+φr” is satisfied, the control for performing drive cutoff is always achieved for Vd2.

### (Memory Circuit)

Since the residual friction force is determined depending on the characteristics of a distortion or sliding mechanism of the rail, the residual friction force may have coordinates dependence and directional dependence. For this reason, if the residual friction force varies according to the positioning coordinates or direction when the positioning is performed by the above-mentioned method, drift may not be sufficiently reduced by using the fixed additional phase value φr or cutoff phase φt. Accordingly, it is preferable that the cutoff phase is stored in association with the moving direction and the coordinates to be used during the positioning.

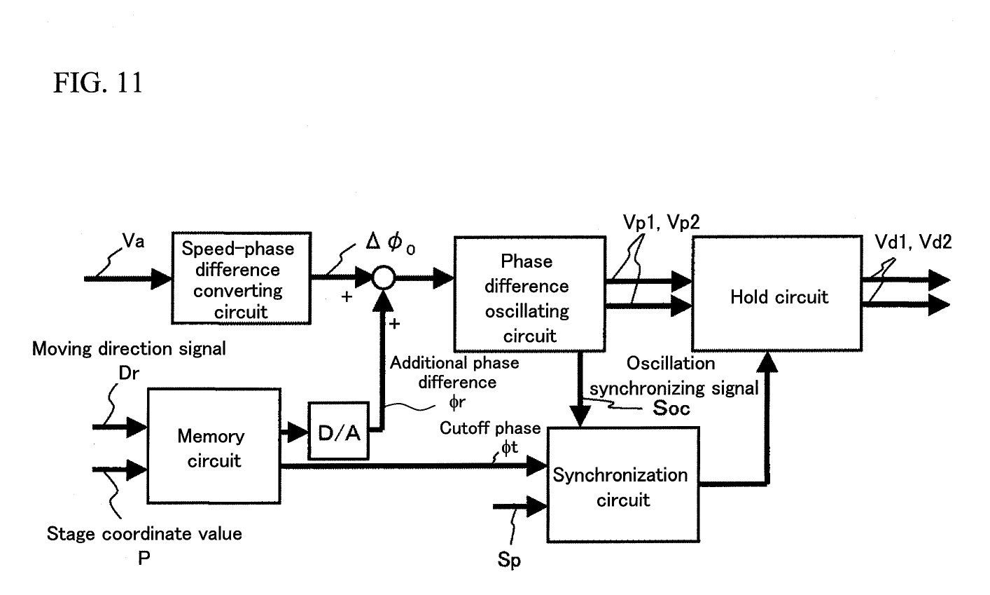

An example of a circuit, which performs this control, is shown in FIG. 11. In FIG. 11, the additional phase value φr and the cutoff phase φt are previously stored in association with a stage coordinate value p and a moving direction signal Dr, and are read out according to the stage coordinate value p and the moving direction signal Dr. The additional phase value φr is added to the phase difference command value Δφo through a DA converter, and the cutoff phase φt is sent to the synchronization circuit.

Meanwhile, the stage coordinate value p may be input momentarily. However, if the stage coordinate value is fixed at a target position at the beginning of the positioning operation, it may be possible to perform a stable control.

### Example 3

### Serial Motor

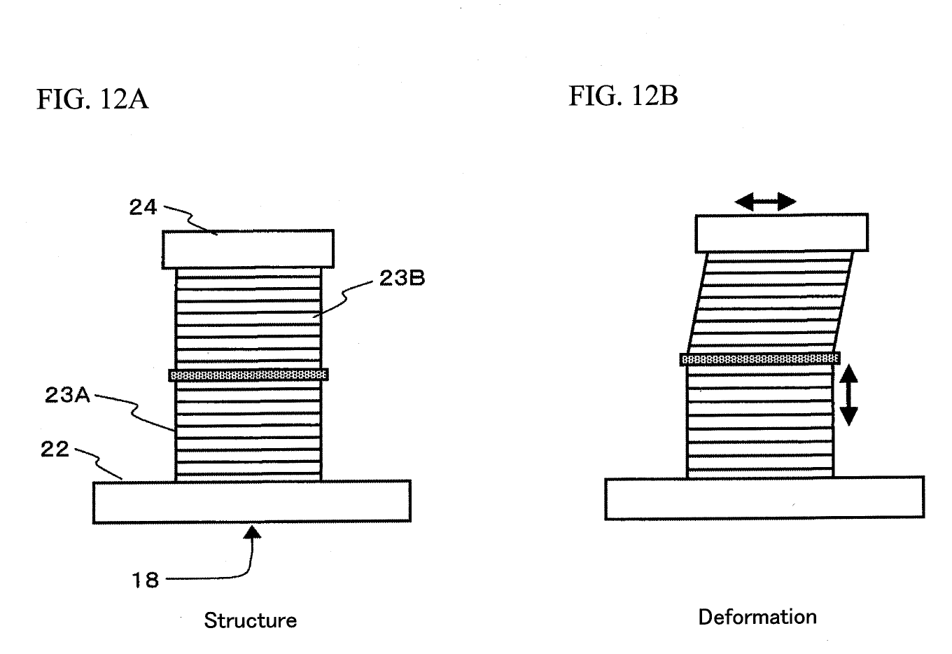

This example provides a method of reducing drift when a serially disposed ultrasonic motor is used unlike in Examples 1 and 2. FIGS. 12A and 12B are views showing a structural example and modification of the serially disposed ultrasonic motor. The ultrasonic motor 18 includes an expandable piezo electric actuator 23A, a shearing piezo electric actuator 23B, and a drive tip 24 that are stacked on a pedestal 22. Like the ultrasonic motor of the above-mentioned example, the trajectory of the drive tip 24 may be controlled by a phase difference between the applied voltages that are applied to the piezo electric actuators. As shown in 12A and 12B, the expandable piezo electric actuator 23A operates to press the drive tip 24 against the drive face, and the hearing piezo electric actuator 23B sliding in the moving direction of the stage operates to move the stage in the moving direction of the stage. The sample stage is moved in a predetermined direction by the cooperation of the two piezo electric actuators.

The same stage as the stage of Example 1 may be used as a stage on which the ultrasonic motor 18 of this example is mounted. Further, the circuit shown in FIG. 10 or 11 may be used as a circuit used for drive. Meanwhile, a relationship between a phase difference and driving speed is slightly different so that maximum speed is obtained at a phase difference of 90° and the driving speed becomes 0 at a phase difference of 0 or 180°. However, there is no essential difference in a driving method.

### (Convergence Point Cutoff Control)

In this example, the piezo electric actuator 23A, which expands or contracts only in the pressing direction, does not affect the drift in the slide direction. Only the piezo electric actuator 23B, which is sheared in the slide direction, affects the drift in the slide direction. Accordingly, there is a demand for the control that makes the residual deformation of the piezo electric actuator 23B be 0. In FIG. 8, the graph, which shows a relationship between the voltage applied to the piezo electric actuator and deformation, intersects with the deformation convergence line at an intersection A or A1. In this example, a cutoff phase is determined so that a voltage applied to the piezo electric actuator 23B is fixed at the intersection. Since the deformation at the time of fixing the applied voltage corresponds to a final deformation convergence value at the intersection A or A1, residual deformation is almost not generated and it may be possible to effectively reduce the drift of the table.

### Example 4

### Measurement of Stop Drag and Compensation of Stage Control Parameter

There has been already described in Example 2 or 3 that the additional phase value φr and the cutoff phase φt need to be previously stored in the memory circuit in order to accurately reduce drift by the circuit of FIG. 11. An example of a specific method thereof will be described in this example.

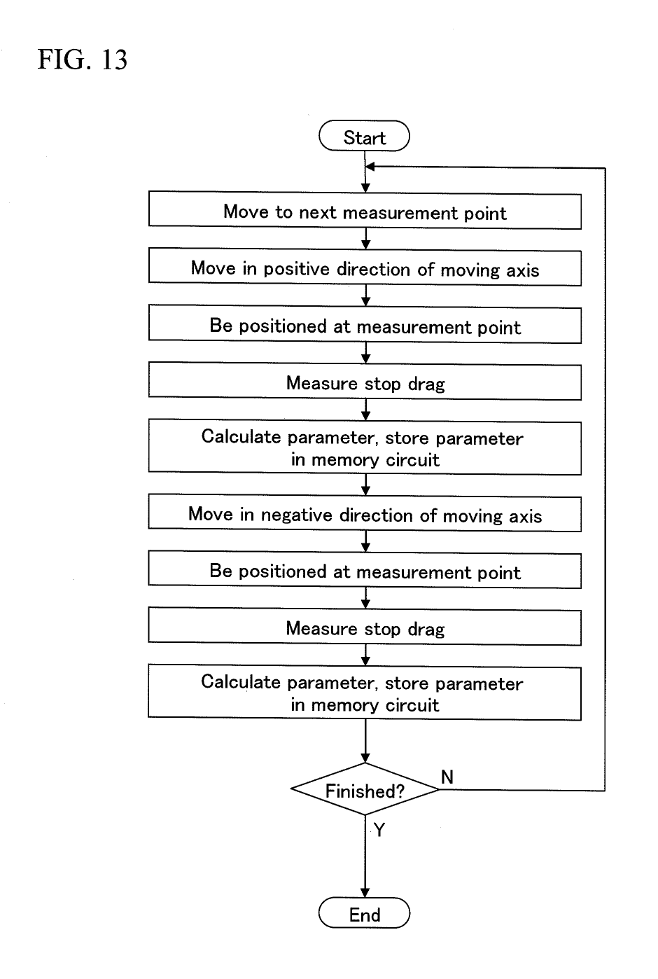

FIG. 13 is a view showing a procedure for calculating φr and φt on the basis of the measurement of a stop drag caused by a residual friction force and storing φr and φt in the memory circuit. First, the table is moved to a measurement position, is moved in a positive direction, and is then positioned at the measurement position. After that, a stop drag is measured. In order to measure the stop drag, there may be considered a method that provides a function of measuring a generated reaction of the ultrasonic motor 18 in the pedestal 22. More simply, there may be used a method of performing the stop by a positioning servo and obtaining a thrust, which is required for the stop, from the phase difference between the voltages that are applied to the piezo electric actuators 23A and 23B at this time. φr and φt, which satisfy the conditions having described in Examples 2 or 3, are calculated from the measured stop drag, and are stored in the memory circuit.

After the procedure corresponding to the positive direction is completed, positioning is performed in a negative direction and storing is performed. The procedures corresponding to both directions are performed for all measurement points, so that storage scanning on the memory circuit is completed.

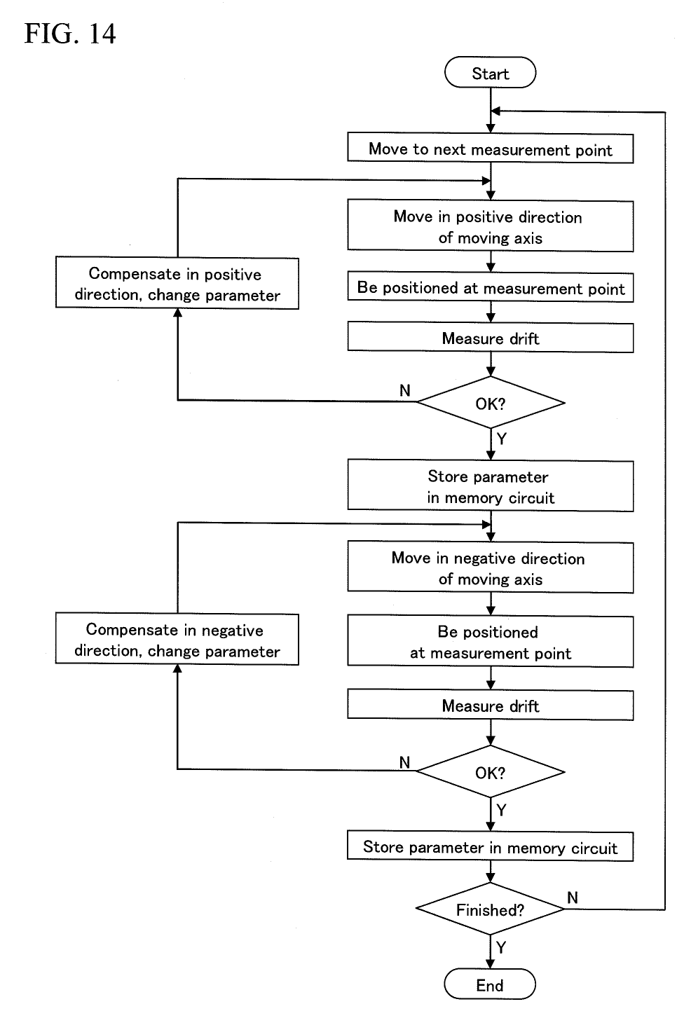

FIG. 14 is a view showing a procedure for determining the additional phase value φr and the cutoff phase φt on the basis of not calculation but actual measurement. The difference between FIGS. 13 and 14 is as follows: positioning is repeated in the same direction while parameters φr and φt are adjusted, a value is determined so that the drift is equal to or smaller than a permissible value, and is stored. As compared to the procedure of FIG. 13, it may be possible to expect more accurate reduction of drift.

Meanwhile, the measurement or compensation needs to be performed for each of the X and Y axes in a stage mechanism including two (X and Y) axes. However, it may be possible to achieve the accurate reduction of drift by setting measurement points, which are disposed in the form of grid points, on the X-Y plane, and performing measurement or compensation on each of the points.

### (Operation Command)

It is considered that the stop drag caused by the residual friction force or the like is changed due to the temporal change caused by the abrasion of parts of a sample stage mechanism, or the service such as maintenance. Accordingly, it is preferable that the contents of the memory circuit of FIG. 11 be automatically updated. For this reason, it is preferable that a command of an apparatus for performing the measurement or compensation is provided, and the memory contents be automatically changed by a command issued by the operator.

Further, in Examples 1 to 3, there has been described a method of reducing drift in consideration of the residual deformation of the piezo electric actuator of the sample stage using the ultrasonic motors. However, even in the case of other linear drive sources such as a linear motor, drift is generated due to a stop drag that is caused by the residual friction force after the positioning. Accordingly, the reduction of the drift, which is caused by the measurement of the stop drag or the compensation of the control parameter in this example, is available in the case of a sample stage using other linear drive sources. In this case, for example, in the case of the drive of the linear motor, a value of holding current flowing through a field coil may be employed as a control parameter in order to maintain a constant thrust after the positioning.

Meanwhile, the invention has been described herein by an example where the invention is applied to a scanning electron microscope (SEM) for inspecting measuring a wafer (sample). The stage apparatus according to the embodiment of the invention is not limited to an SEM. The invention may also be applied to general charged particle beam apparatuses, such as an electron beam drawing apparatus and an FIB, that include stage devices for picking up a sample and moving the sample in two (X and Y) directions. In addition, the invention is not limited to the charged particle beam apparatus, and may also be applied to an optical inspection apparatus that inspects foreign materials or defects by light scattering. Further, the sample to be held is not limited to a wafer, and may be applied to inspect and measure a sample having fine patterns, such as a reticle for lithography and a mask.

The invention may be suitable for a charged particle beam apparatus such as an electron microscope for inspection and measurement in a field of manufacture of a semiconductor device, and a sample stage mechanism used for the charged particle beam apparatus.

### DESCRIPTION OF THE REFERENCE NUMERALS

1: CHARGED-PARTICLE OPTICAL SYSTEM
2: SAMPLE CHAMBER
7: WAFER
13: BASE
14: X TABLE
15: Y TABLE
16: CHUCK
18: ULTRASONIC MOTOR
19: RAIL
20: PEDESTAL
22: MOTOR BASE
23A, 23B: PIEZO ELECTRIC ACTUATOR
24: DRIVE TIP

1. A sample stage for electron microscope including a table that moves a target sample in a predetermined direction, the sample stage comprising:
a drive mechanism that moves the table in the predetermined direction; and
a face for receiving a pressing force by the drive mechanism,
wherein the drive mechanism includes at least two piezo electric actuators, and is arranged to move the table in the predetermined direction by a cooperation of the two piezo electric actuators, and when the sample stage is stopped, a phase difference between voltages applied to the two piezo electric actuators is adjusted to be reduced.

2. The sample stage according to claim 1,
wherein the two piezo electric actuators are disposed so as to expand and contract in a direction inclined with respect to the face for receiving the pressing force.

3. The sample stage according to claim 1, comprising:
a first piezo electric actuator that is provided in a plane including first and second straight lines and expands and contracts in a direction of a third straight line intersecting with the second straight line, the first straight line being a line perpendicular to the face, the second straight line passing through an intersection of the first straight line and the face and being parallel to a moving direction of the table;
a second piezo electric actuator that is provided in the plane and expands and contracts in a direction of a fourth straight line, which is symmetry with the third line about the first straight line; and
a press part that is formed at portions of the first and second piezo electric actuators close to the table, and is pressed against the face by the cooperation of the first and second piezo electric actuators.

4. The sample stage according to claim 1,
wherein the drive mechanism keeps a state where the phase difference becomes zero, for a predetermined time.

5. A sample stage for electron microscope including a table that moves a target sample in a predetermined direction, the sample stage comprising:
a drive mechanism that moves the table in the predetermined direction; and
a face for receiving a pressing force of the drive mechanism,
wherein the drive mechanism includes at least two piezo electric actuators, and is arranged to move the table in the predetermined direction by a cooperation of the two piezo electric actuators, and
when the sample stage is stopped, voltages applied to the two piezo electric actuators are fixed at a time when phases of the voltages applied to the two piezo electric actuators become predetermined phases.

6. The sample stage according to claim 5,
wherein each of the phases is a phase corresponding to a point where a deformation response to the applied voltage by the piezo electric actuator intersects with a deformation contraction point of the piezo electric actuator.

7. An electron microscope comprising:
a sample stage that is driven by an ultrasonic motor including a pair of piezo electric actuators; and
a control circuit that controls the sample stage,
wherein the control circuit includes a phase difference oscillating circuit that controls a phase difference of a variations of a voltages respectively applied to the pair of the piezo electric actuators of the ultrasonic motor, and a delay circuit and a hold circuit for maintaining the phase difference of the variations of the applied voltages for a predetermined time after positioning conditions are satisfied and then fixing the phase difference.

8. The electron microscope according to claim 7, further comprising:
a memory circuit that stores a phase difference value to be added to an input of the phase difference oscillating circuit in association with a moving direction of the stage and a positioning coordinate.

9. An electron microscope comprising:
a sample stage that is driven by an ultrasonic motor; and
a control circuit that controls the sample stage,
wherein the control circuit includes a phase difference oscillating circuit that controls a phase difference of a variations of a voltages respectively applied to a pair of the piezo electric actuators of the ultrasonic motor, and a synchronization circuit and a hold circuit for fixing the applied voltages at a time when the applied voltages reach predetermined phases after positioning conditions are satisfied.

10. The electron microscope according to claim 9, further comprising:
a memory circuit that stores a phase difference value to be added to an input of the phase difference oscillating circuit and a cutoff phase to be input to the fixing circuit in association with positioning coordinates and a moving direction of the stage.

11. An electron microscope including a sample stage that is driven by a linear drive source, such as an ultrasonic motor or a linear motor,
comprising a mechanism, in which steps for (1) positioning the sample stage, and (2) evaluating a stage drag while stopping in positioning are performed for the positioning from both directions of a moving axis at points of a plurality of coordinates that are disposed within a movement stroke of the sample stage, so as to measure the distribution of a stop drag of the stage within the movement stroke, and then based on the measurement result, drift during the positioning of the stage is reduced.

12. An electron microscope comprising:
a sample stage that is driven by a linear drive source, such as an ultrasonic motor or a linear motor,
comprising a mechanism, in which steps for (1) positioning the sample stage, (2) evaluating drift after stop, and (3) compensating a control parameter of the stage are repeated, so as to reduce a stop drift of the stage within the movement stroke.

13. The electron microscope according to claim 11,
wherein the mechanism for reducing the stop drift is automatically performed by the issuing an operation command.

14. A sample stage for electron microscope including a table that moves a target sample in a predetermined direction, the sample stage comprising:
a drive mechanism that moves the table in the predetermined direction; and
a face for receiving a pressing force of the drive mechanism,
wherein the drive mechanism includes:
a first actuator that is provided in a plane including a first and second straight lines and expands and contracts in a direction of a third straight line intersecting with the second straight line, the first straight line being a line perpendicular to the face, the second straight passing through an intersection of the first straight line and the face and being parallel to a moving direction of the table,
a second actuator that is provided in the plane and expands and contracts in a direction of a fourth straight line that is symmetry with the third straight line about the first straight line; and
a press part that is formed at portions of the first and second actuators close to the face, and is pressed against the face by a cooperation of the first and second actuators.

15. A sample stage for electron microscope including a table that moves a target sample in a predetermined direction, the sample stage comprising:
a drive mechanism that moves the table in the predetermined direction; and
a face for receiving a pressing force of the drive mechanism,
wherein the drive mechanism includes a structure formed by stacking an expandable piezo electric actuator, a shearing piezo electric actuator, and a press part that presses the face in an expansion-contraction direction of the expandable piezo electric actuator,
the expandable piezo electric actuator operates to press the press part against the face, and
the shearing piezo electric actuator operates to move the stage in the predetermined direction.

16. The electron microscope according to claim 12,
wherein the mechanism for reducing the stop drift is automatically performed by the issuing an operation command.
